(19) United States
(12) Patent Application Publication
(10) Pub. No.: US 2002/0187629 A1
(43) Pub. Date: Dec. 12, 2002

(54) Method for dual damascene process without using gap-filling materials

(76) Inventors: I-Hsiung Huang, Kaohsiung City (TW); Jiunn-Ren Hwang, Hsinchu City (TW); Ya-Hui Chang, Ping-Tung (TW); Chien-Mei Wang, Hsin-Chu City (TW)

Correspondence Address: POWELL, GOLDSTEIN, FRAZER & MURPHY LLP, P.O. BOX 97223, Washington, DC, 20090-7223, US

(21) Appl. No.: 09/874,523

(22) Filed: Jun. 6, 2001

(51) Int. Cl. H01L 21/4763

(52) U.S. Cl. 438/624; 438/638; 438/637

(57) ABSTRACT

This method comprising a stop layer, a dielectric layer, a bottom hard layer and top hard mask layer are formed on a substrate, sequentially. A via pattern photoresist layer is formed on the top hard mask layer. The top hard mask layer is etched by using the via pattern photoresist layer as a mask to transfer the via pattern into the top hard mask layer then removed the via pattern photoresist layer. A trench pattern photoresist layer is formed on the top hard mask layer wherein the trench pattern is over the via pattern. The bottom hard mask layer is etched by using the top hard mask layer as a mask to transfer the via pattern into the bottom hard mask layer. The top hard mask layer is etched by using the trench pattern photoresist layer as a mask, wherein the via pattern is transferred into a portion of the dielectric layer. The bottom hard mask layer is etched by using the top hard mask layer as a mask, wherein the via pattern is transferred into the dielectric layer. The dielectric layer is etched by using the bottom hard mask layer as a mask to form a via hole and a trench line in the dielectric layer, wherein the trench line is over the via hole, and the via hole exposes a portion of the substrate.

### BACKGROUND OF THE INVENTION

1. Field of the Invention

This invention relates generally to fabrication of a semiconductor device and more particularly to a method for forming a dual damascene structure without using gap-filling material.

2. Description of the Prior Art

Dual damascene etching creates trenches for lines and holes for vias, which are then simultaneously metallized to form the interconnect wiring. Dual damascene processes including self-aligned dual damascene (SADD), via-first dual damascene (VFDD) and trench-first dual damascene (TFDD). Self-aligned dual damascene method needs a thick intermediate layer to serve as a photo anti-reflection layer and a etching stopping layer. This extra layer causes a larger RC delay and extra substrate stress. Trench-first dual damascene method will induce resist thickness variation on topography that will product resist footing and residues. Trench-first dual damascene method will also suffer the gap filling capability of Cu plating out of photo misalignment. Currently, very few company use self-aligned dual damascene method or trench-first dual damascene method to define dual damascene structure.

About to via-first dual damascene method, conventional via-first dual damascene process as shown in FIGS. 1A through 1H. There is a conductive layer 15 on a substrate 10. A first stop layer 20, a first dielectric layer 25, a second stop layer 30, a second dielectric layer 35 and a hard mask layer 40 are formed on the conductive layer 15, respectively, as shown in FIG. 1A. A first bottom anti-reflectivity coating (BARC) layer 45 is formed on the hard mask layer 40. A first photoresist layer 50 is formed on the first BARC layer 45 wherein the first photoresist layer 50 has a via pattern 55, as shown in FIG. 1B.

Then, an etch process is performed by using the first photoresist layer 50 as a mask to form a via opening 55-1 from first BARC layer 45 to expose the first stop layer 20, and the first photoresist layer 50 and the first BARC layer 45 are then removed, as shown in FIG. 1C. Next, a gap-filling material 60 is filled to the via opening 55-1. The gap-filling material 60 will cross-linked when fill into the via opening 55-1, as shown in FIG. 1D.

A second BARC layer 65 is formed over the hard mask layer 40 and via opening 55-1. A second photoresist layer 70 is formed on the second BARC layer 65 wherein the second photoresist layer 70 has a trench pattern 75, as shown in FIG. 1E. Next, an etch step is utilized to remove the exposed portion from the second BARC layer 65 to second stop layer 30 to form a trench opening 75-1. But, the interaction between gap-filling material 60 and second dielectric layer 35 to form a fence 80 on the via opening 55-1 sidewall, as shown in FIG. 1F.

Next, the second photoresist layer 70, second BARC layer 65 and the gap-filling material 60 are then removed, as shown in FIG. 1G. To be continue, the second stop layer 30 and the first stop layer 20 are etched to expose the first dielectric layer 25 and the conductive layer 20. However, the fence 80 is difficult to removed. Thus, the resulting structure is a conventional via-first dual damascene structure illustrated in FIG. 1H.

In the conventional via-first dual damascene method, they are many drawback, such as need gap-filling material that will interaction with dielectric layer and easy produce fence. In this process need deposited two times BARC layer and the flow become complex. In this process need BARC layer to controlled high reflectivity variation. In this process thicker BARC layer will reducing ADI/AEI (after developing inspection/ after etching inspection) bias.

### SUMMARY OF THE INVENTION

In accordance with the present invention, it is a main object of this invention to form a dual damascene structure without using gap-filling materials.

It is another object of this invention without using gap-filling materials to avoided fence issue and improving CD uniformity.

It is another object of this invention by using silicon oxynitride as a hard mask layer and anti-reflectivity coating layer to reducing BARC cost.

It is another object of this invention, silicon oxynitride can be reducing reflectivity variation is better than BARC.

It is another object of this invention the dual damascene process flow is simpler and easy to define dual damascene structure.

It is another object of this invention can be reducing ADI/AEI (after developing inspection/after etching inspection) bias.

It is another object of this invention can be increasing throughout effectively.

In this invention, they didn't need to use gap-filling material to avoid resist residue. The other advantage is resist will not touch to low-k material because dual hard mask layer approach. It will reduce the poison issue out of the interaction between resist and low-k material.

In this invention, use silicon oxynitride film to be top hard mask layer and silicon carbide film to be bottom hard mask layer. Silicon oxynitride is not only a good hard mask layer film but also a good inorganic anti-reflectivity coating (ARC) layer. Especially, when the thickness of silicon oxynitride film is over 1500 angstrom. It will make the reflectivity variation shrink to saturation by absorptance. By the way, photo resist will easily define pattern due to effectively controlling substrate reflectivity variation. In addition to good ARC effect, the etch selectivity of silicon oxynitride is much better than oxide to the low-k dielectric material. The bottom hard mask layer is silicon carbide film that has low-k dielectric value to reduce RC delay to improve device performance.

A method for forming dual damascene structure without using gap-filling materials comprising a stop layer, a dielectric layer, a bottom hard layer and top hard mask layer are formed on a substrate, sequentially. A via pattern photoresist layer is formed on the top hard mask layer. The top hard mask layer is etched by using the via pattern photoresist layer as a mask to transfer the via pattern into the top hard mask layer then removed the via pattern photoresist layer. A trench pattern photoresist layer is formed on the top hard mask layer wherein the trench pattern is over the via pattern. The bottom hard mask layer is etched by using the top hard mask layer as a mask to transfer the via pattern into the bottom hard mask layer. The top hard mask layer is etched by using the trench pattern photoresist layer as a mask, wherein the via pattern is transferred into a portion of the dielectric layer. The bottom hard mask layer is etched by using the top hard mask layer as a mask, wherein the via pattern is transferred into the dielectric layer. The dielectric layer is etched by using the bottom hard mask layer as a mask to form a via hole and a trench line in the dielectric layer, wherein the trench line is over the via hole, and the via hole exposes a portion of the substrate.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1A through 1H illustrate sequential sectional views of a conventional process for forming a dual damascene structure with using gap-filling materials to obtain a fence.

FIGS. 2A through 2I illustrates sequential sectional views of a process for forming a dual damascene structure without using gap-filling materials according to the invention.

FIGS. 3A through 3I illustrate sequential sectional views of a process for forming a dual damascene structure without using gap-filling materials according to the invention.

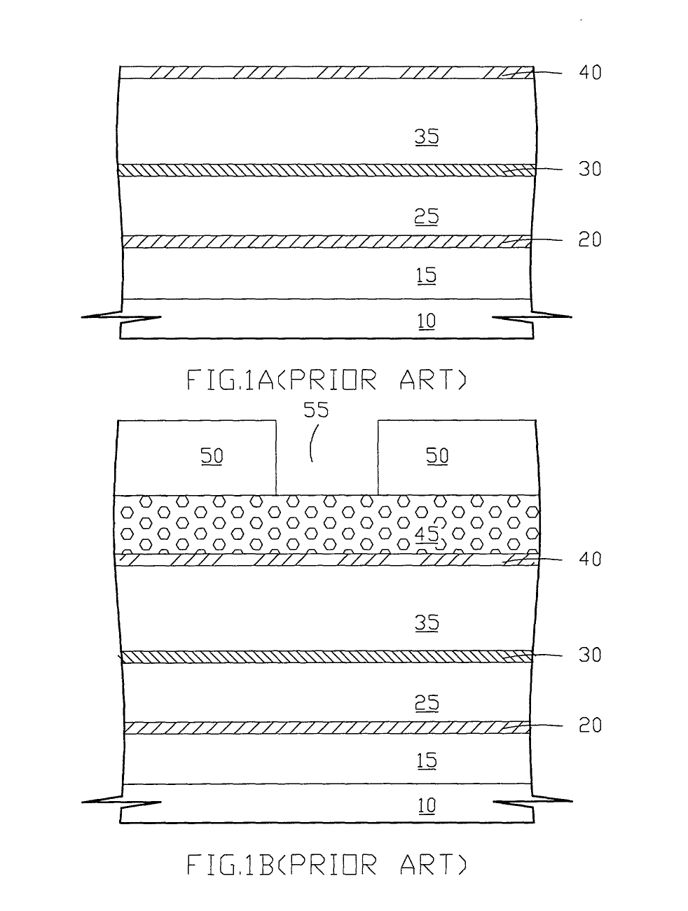

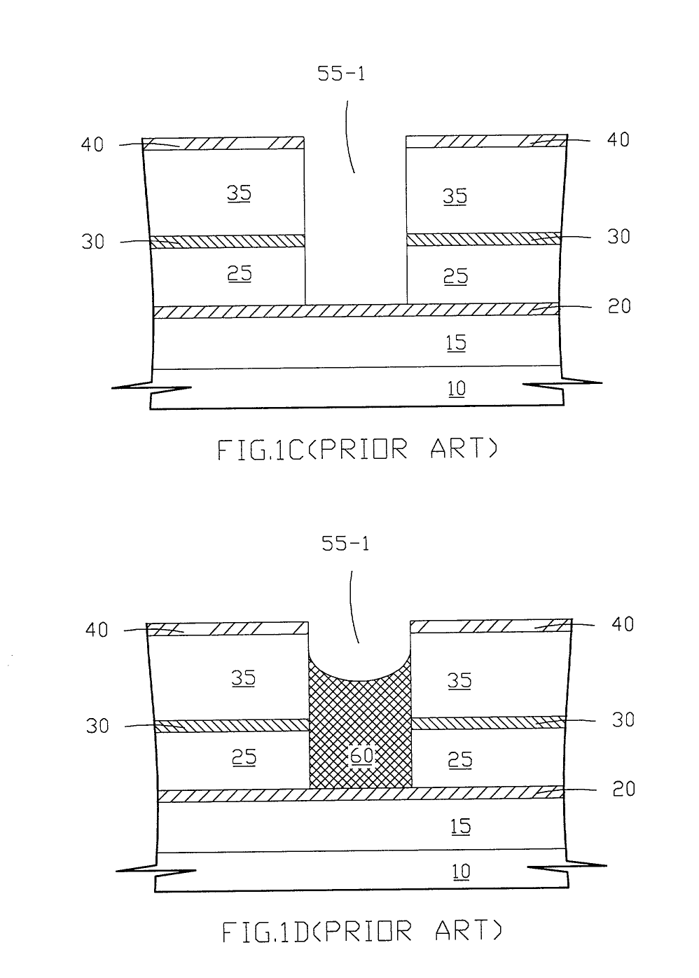

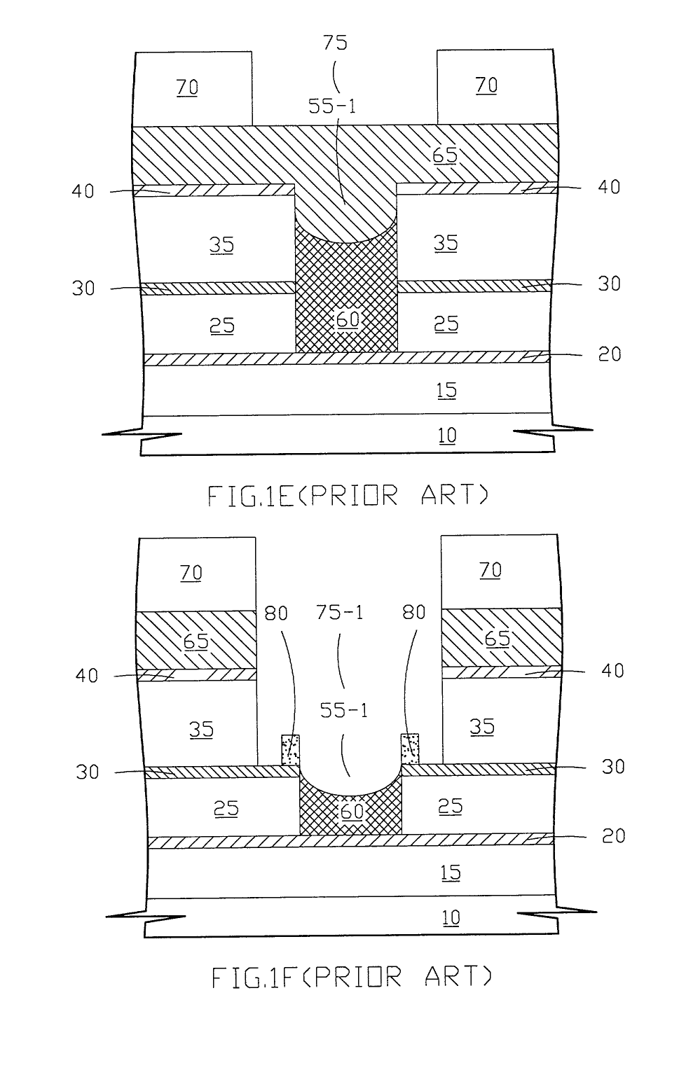

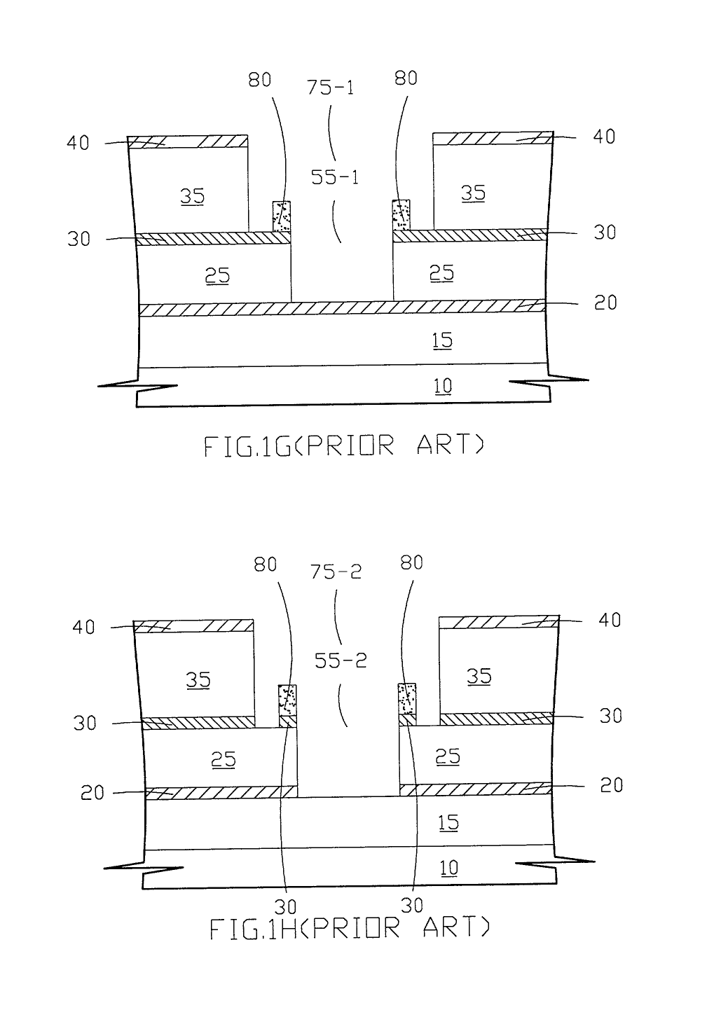

### DESCRIPTION OF THE PREFERRED EMBODIMENT

The present invention will be described in detail with reference to the accompanying drawings. The present invention provides a method for forming a dual damascene structure without using gap-filling materials.

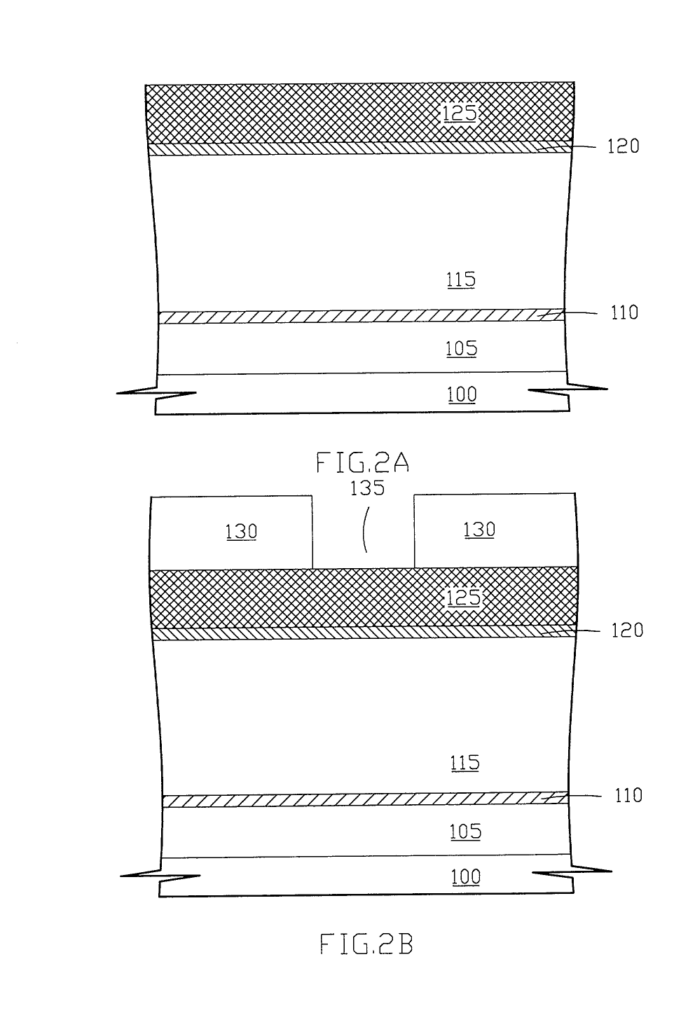

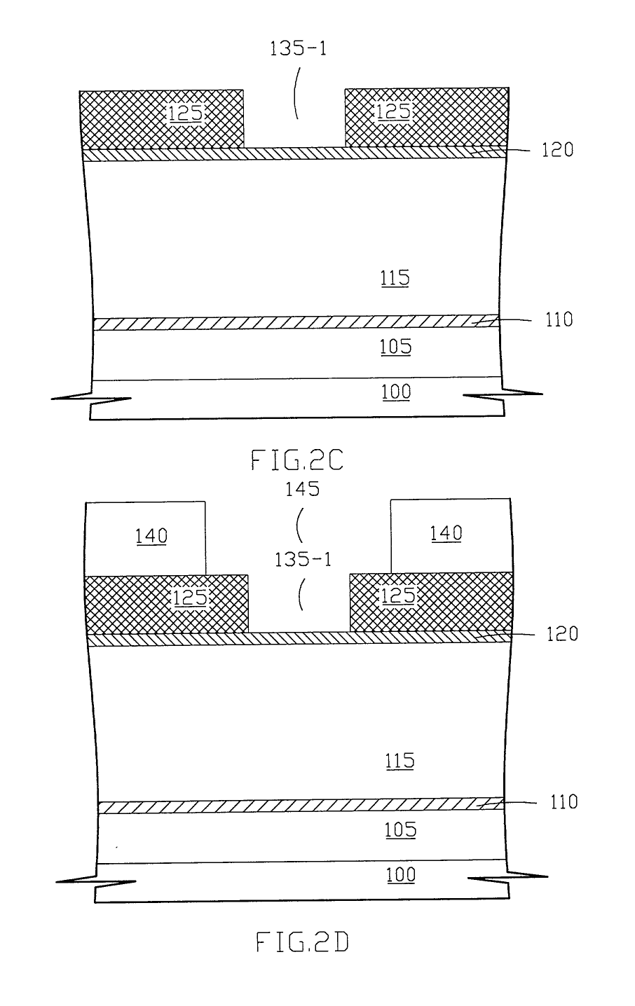

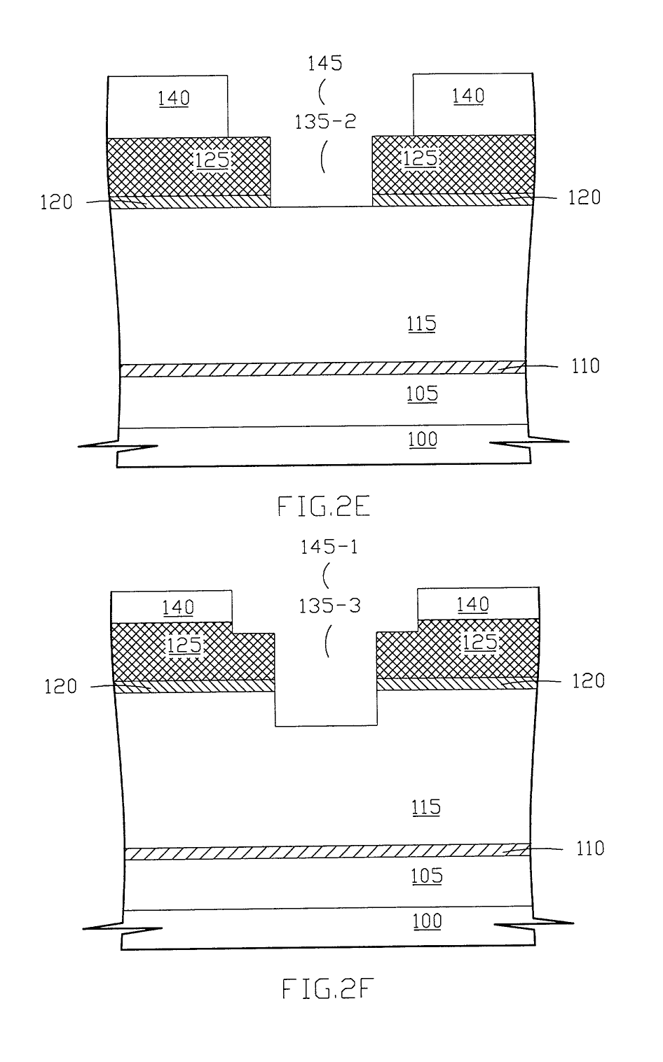

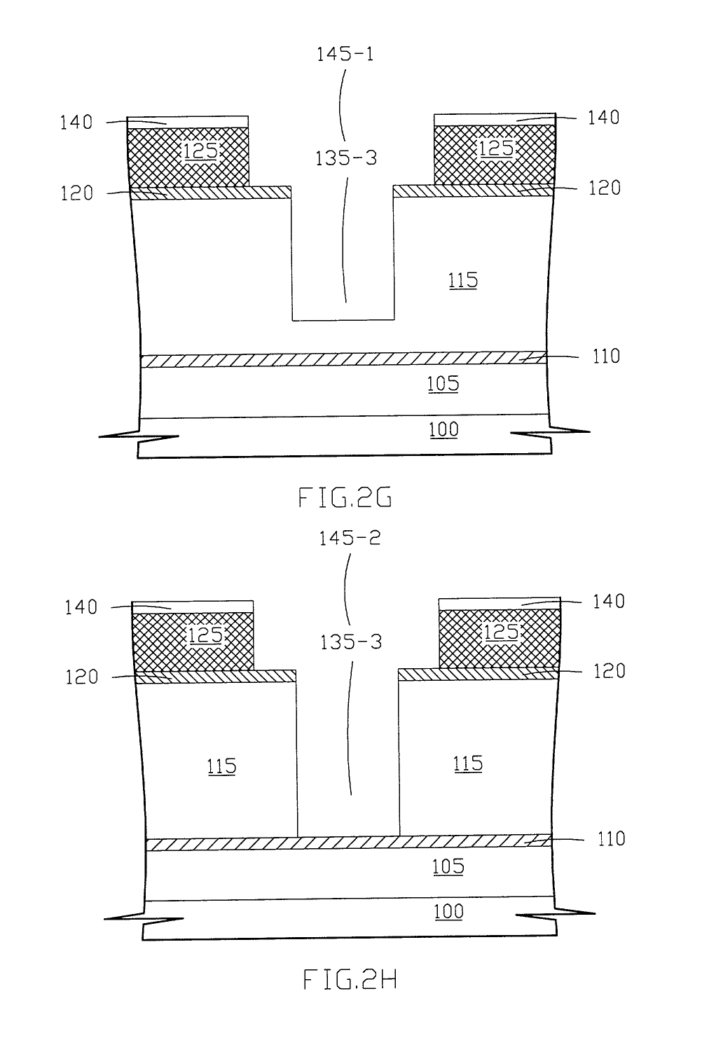

The preferred embodiment of the present invention begins by providing a semiconductor structure. The semiconductor structure having a substrate 100, a conductive layer 105 on the substrate 100, a stop layer 110 on the conductive layer 105, a dielectric layer 115 on the stop layer 110, a bottom hard mask layer 120 on the dielectric layer 115 and top hard mask layer 125 on the bottom hard mask layer 120, shown in FIG. 2A.

The conductive layer 105 can be comprise a metal, most preferably copper, aluminum or any other conductive material such as doped silicon is formed on the substrate 100. Typically, the conductive layer 105 is an interconnect pattern or line. In a preferred embodiment, the conductive layer 105 is a copper.

The stop layer 110 can be comprise silicon nitride, carbon nitride, boron nitride, boron carbon nitride or silicon carbide, reduces capacitance between conductive structures. Reduced capacitance provides a key advantage in performance and reliability for sub-micron devices. In a preferred embodiment, the stop layer 110 is a silicon carbide layer.

The dielectric layer 115 is a low-k dielectric material comprising an insulating material, such as silicon dioxide, hydrogen-doped silicon dioxide, fluorine-doped silicon dioxide, carbon-doped silicon dioxide, an organic polymer (comprising carbon and hydrogen), or a fluorine-doped organic polymer. In a preferred embodiment, the dielectric layer 115 is a fluorine-doped organic polymer layer.

The bottom hard mask layer 120 can be comprising silicon nitride, silicon carbide, carbon nitride, boron nitride, or boron carbon nitride. In a preferred embodiment, the bottom hard mask layer 120 is a silicon carbide layer, thickness is about 25 nm and about 100 nm that has a low-k dielectric value to reduce RC delay to improve device performance.

The top hard mask layer 125 is preferably silicon oxynitride, silicon oxime or silicon nitride. The deposition of top hard mask layer 125 by conventional CVD techniques or typical spin-on organic hard mask materials. They creates a more uniform layer and provide better process control. In a preferred embodiment, the top hard mask layer 125 is a silicon oxynitride layer, has thickness about 100 nm and about 200 nm, that has been deposited using PECVD or LPCVD.

In this invention, by using silicon oxynitride film to be top hard mask layer 125. Silicon oxynitride is not only a good hard mask film but also a good inorganic anti-reflectivity coating (ARC). Especially, when the thickness of silicon oxynitride film is over 1500 angstrom. It will make the reflectivity variation shrink to saturation by absorpance. By the way, photoresist layer will easily define patterning due to effectively controlling substrate reflectivity variation. In addition to good anti-reflectivity coating effect, the etch selectivity of silicon oxynitride is much better than oxide to the low-k dielectric material. It will help to control the top hard mask layer 125 thickness about 1500 angstrom to reduce step height issue from coating via resist.

Next, as shown in FIG. 2B, a first photoresist layer 130 is formed on the top hard mask layer 125 wherein the first photoresist layer 130 has a via pattern 135. The top hard mask layer 125 is etched by using the first photoresist layer 130 as a mask to transfer the via pattern 135 into the top hard mask layer 125 to form a via opening 135-1, and then the first photoresist layer 130 is removed, as shown in FIG. 2C.

Next, as shown in FIG. 2D, a second photoresist layer 140 is formed on the top hard mask layer 125 wherein the second photoresist layer 140 has a trench pattern 145. The trench pattern 145 is over the via opening 135-1. The bottom hard mask layer 120 is etched by using the top hard mask layer 125 as a mask to transfer the via opening 135-1 into the bottom hard mask layer 120 to form via opening 135-2, as shown in FIG. 2E.

Next, as shown in FIGS. 2F and 2G, the top hard mask layer 125 is etched by using the second photoresist layer 140 as a mask to form trench opening 145-1, wherein the via opening 135-2 is transferred in to a portion of the dielectric layer 115 to form via opening 135-3.

Next, as shown in FIG. 2H, the bottom hard layer 120 is etched by using the top hard mask layer 125 as a mask to form trench opening 145-2, wherein the via openingl35-3 is transferred into the dielectric layer 115. The dielectric layer 115 is etched by using the bottom hard mask layer 120 as a mask to form a via hole 135-3 and a trench line 145-2 in the dielectric layer 115, wherein the trench line 145-3 is over the via hole 135-4.

Next, as shown in FIG. 2I, the second photoresist layer 140 is removed. The stop layer 110 is etched by using the top hard mask layer 125 as a mask, then the via hole 135-4 exposes a portion of the conductive layer 110.

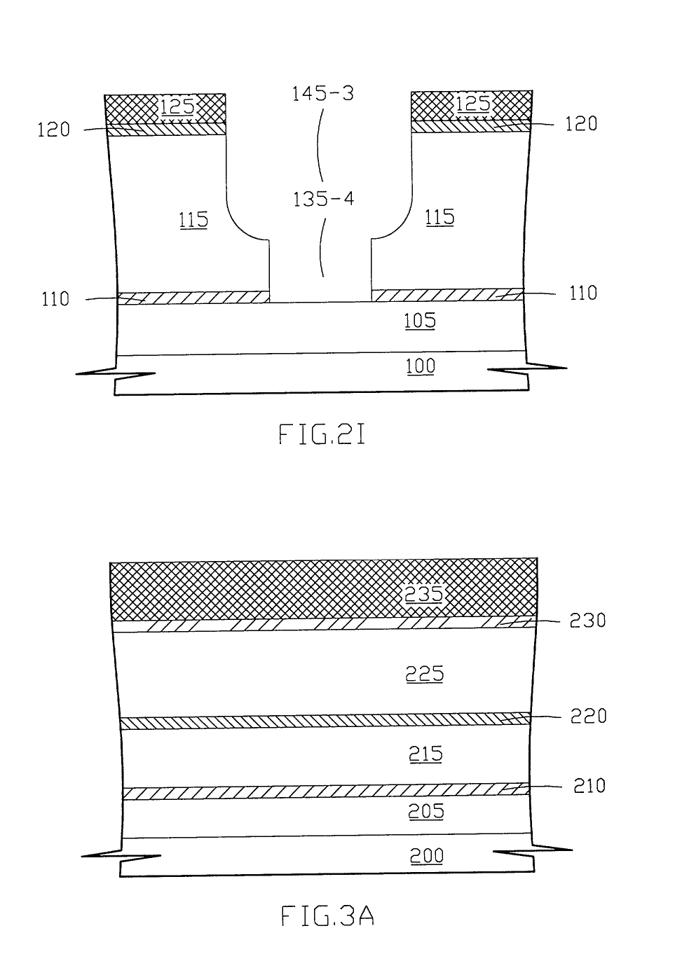

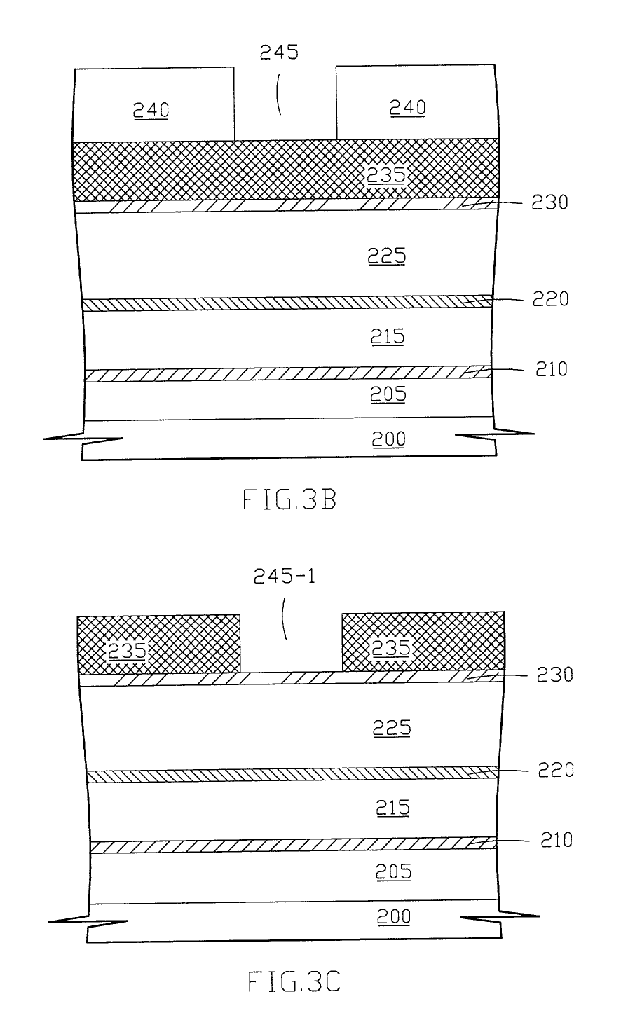

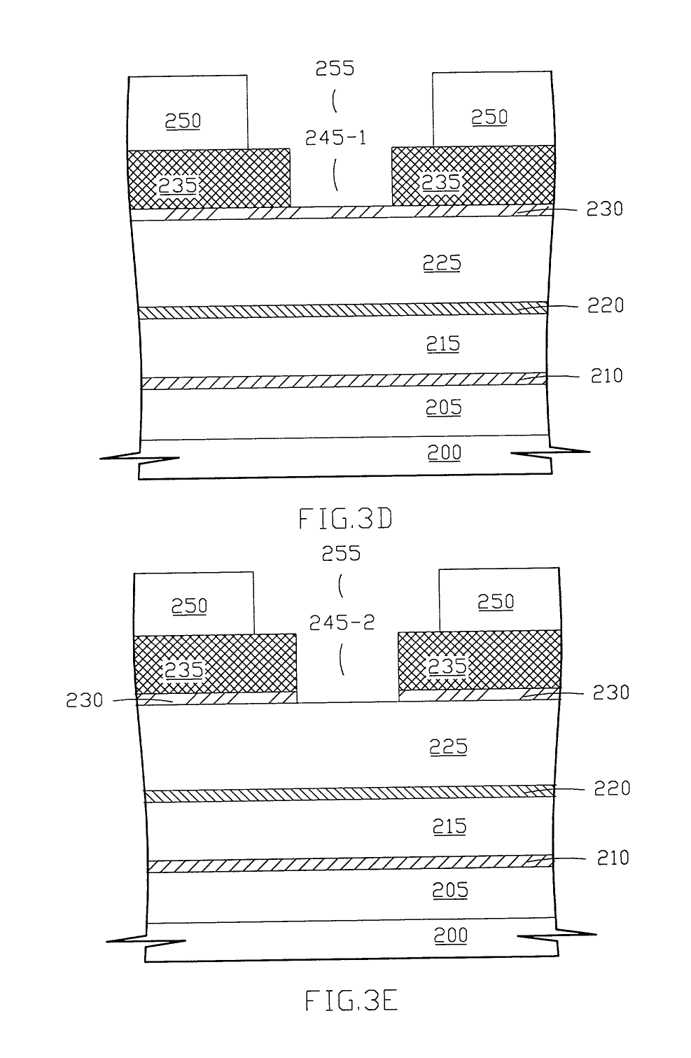

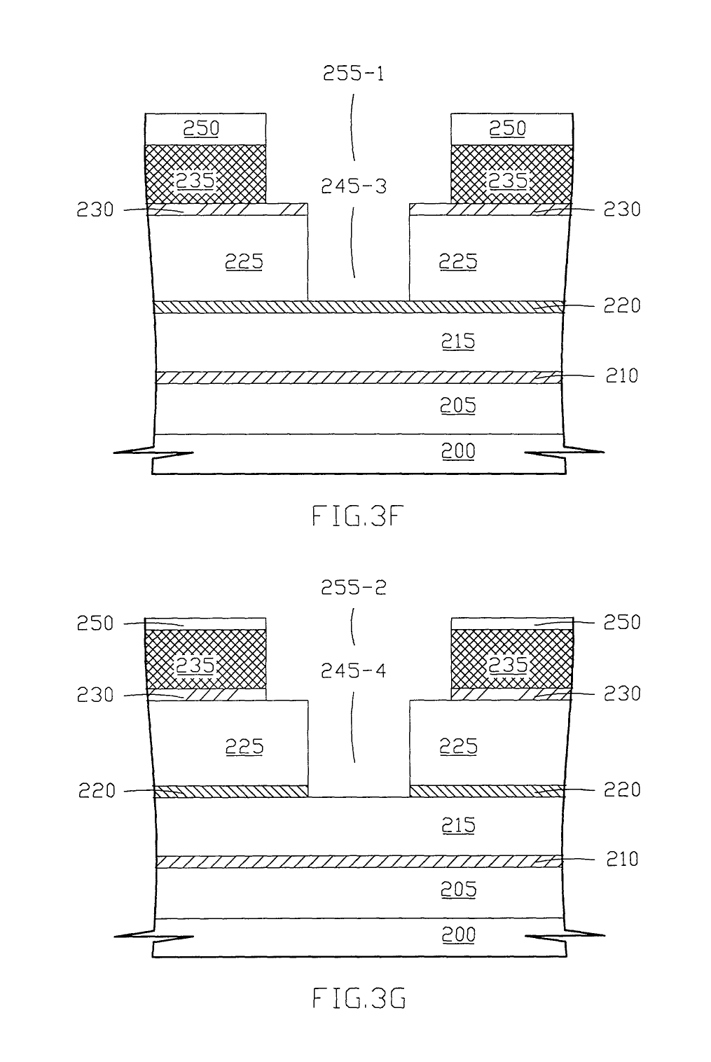

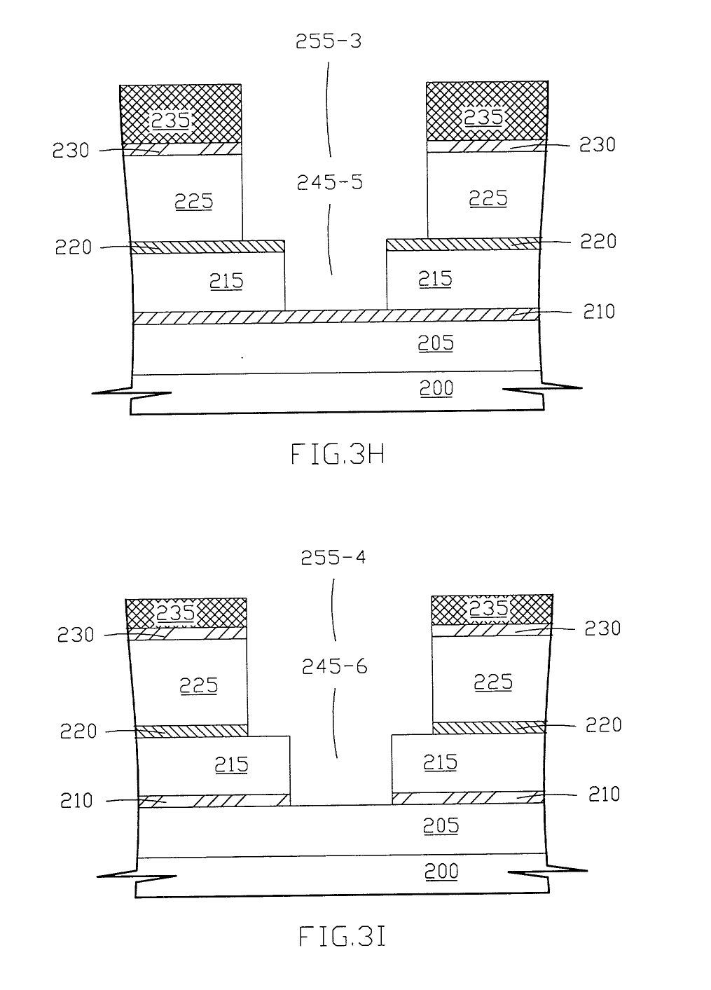

FIG. 3A shows an alternate dual damascene structure formed according to the present invention. The semiconductor structure having a substrate 200, a conductive layer 205 on the substrate 200, a first stop layer 210 on the conductive layer 205, a first dielectric layer 215 on the first stop layer 210, a second stop layer 220 on the first dielectric layer 215, a second dielectric layer 225 on the second stop layer 220, a bottom hard mask layer 230 on the second dielectric layer 225 and top hard mask layer 235 on the bottom hard mask layer 230.

The conductive layer 205 can be comprise a metal, most preferably copper, aluminum or any other conductive material such as doped silicon is formed on the substrate 200. Typically, the conductive layer 205 is an interconnect pattern or line. In a preferred embodiment, the conductive layer 205 is a copper.

The first stop layer 210 and second stop layer 220 are comprise silicon nitride, carbon nitride, boron nitride, boron carbon nitride or silicon carbide, reduces capacitance between conductive structures. Reduced capacitance provides a key advantage in performance and reliability for sub-micron devices. In this embodiment, the first stop layer 210 and second stop 220 can be same material or difference material.

The first dielectric layer 215 and second dielectric layer 225 are low-k dielectric material comprising an insulating material, such as silicon dioxide, hydrogen-doped silicon dioxide, fluorine-doped silicon dioxide, carbon-doped silicon dioxide, an organic polymer (comprising carbon and hydrogen), or a fluorine-doped organic polymer. In this embodiment, the dielectric layer 215 and the second dielectric layer 225 can be same material or difference material.

The bottom hard mask layer 230 can be comprising silicon nitride, silicon carbide, carbon nitride, boron nitride, or boron carbon nitride reduces capacitance between conductive structures. In a preferred embodiment, the bottom hard mask layer 230 is a silicon carbide layer, thickness is about 25 nm and about 100 nm that has low-k dielectric value to reduce RC delay to improve device performance.

The top hard mask layer 235 is preferably silicon oxynitride, silicon oxime, or silicon nitride. The deposition of top hard mask layer 235 by conventional CVD techniques or typical spin-on organic hard mask material. They creates a more uniform layer and provide better process control. In a preferred embodiment, the top hard mask layer 235 is a silicon oxynitride layer, has thickness about 100 nm and about 200 nm, that has been deposited using PECVD or LPCVD.

In this invention, by using silicon oxynitride film to be top hard mask layer 235. Silicon oxynitride is not only a good hard mask film but also a good inorganic anti-reflectivity coating (ARC). Especially, when the thickness of silicon oxynitride film is over 1500 angstrom. It will make the reflectivity variation shrink to saturation by absorpance. By the way, photoresist layer will easily define patterning due to effectively controlling substrate reflectivity variation. In addition to good anti-reflectivity coating effect, the etch selectivity of silicon oxynitride is much better than oxide to the low-k dielectric material. It will help to control the top hard mask layer 235 thickness about 1500 angstrom to reduce step height issue from coating via resist.

Next, as shown in FIG. 3B, a first photoresist layer 240 is formed on the top hard mask layer 235 wherein the first photoresist layer 240 has a via pattern 245. The top hard mask layer 235 is etched by using the first photoresist layer 240 as a mask to transfer the via pattern 245 into the top hard mask layer 235 to form a via opening 245-1, and then the first photoresist layer 240 is removed, as shown in FIG. 3C.

Next, as shown in FIG. 3D, a second photoresist layer 250 is formed on the top hard mask layer 235 wherein the second photoresist layer 250 has a trench pattern 255. The trench pattern 255 is over the via opening 245-1. The bottom hard mask layer 230 is etched by using the top hard mask layer 235 as a mask to transfer the via opening 245-1 into the bottom hard mask layer 230 to form via opening 245-2, as shown in FIG. 3E.

Next, as shown in FIG. 2F, the top hard mask layer 235 is etched by using the second photoresist layer 250 as a mask to form trench opening 255-1, wherein the via opening 245-2 is transferred into the second dielectric layer 225 to form via opening 245-3.

Next, as shown in FIG. 3G, the bottom hard mask layer 230 is etched by using the top hard mask layer 235 as a mask to form trench opening 255-2 wherein the via opening 245-3 is transferred into the second stop layer 220 to form via opening 245-4.

Next, as shown in FIG. 3H, the second photoresist layer 250 is removed. The second dielectric layer 225 is etched by using bottom hard mask layer 230 as a mask to form trench opening 255-3 wherein the via opening 245-4 is transferred into the first dielectric layer 215 to form via opening 245-5.

Next, as shown in FIG. 3I, the second stop layer 220 is etched by using the top hard mask layer 235 as a mask wherein the via opening 245-5 is transferred in the first stop layer 210 to form a via hole 245-6 and trench line 255-4, then the via hole 245-6 exposes a portion of the conductive layer 210.

While the invention has been particularly shown and described with reference to the preferred embodiments thereof, it will be understood by those skilled in the art that various changes in form and details may be made without departing from the spirit and scope of the invention. For example, although a via first, dual damascene process is described for illustrative purposes, the invention can also be used for other damascene processes.

What is claimed is:

1. A method for forming dual damascene structure without using gap-filling material, said method comprising:
providing a semiconductor structure having a substrate, a dielectric layer on said substrate, a first hard mask layer on said dielectric layer, a second hard mask layer on said first hard mask layer;
forming a via pattern photoresist layer on said second hard mask layer;
etching said second hard mask layer by using said via pattern photoresist layer as a mask to transfer said via pattern into said second hard mask layer;
removing said via pattern photoresist layer;
forming a trench pattern photoresist layer on said second hard mask layer, wherein said trench pattern is over said via pattern;
etching said first hard mask layer by using said second hard mask layer as a mask to transfer said via pattern into said first hard mask layer;
etching said second hard mask layer by using said trench pattern photoresist layer as a mask, wherein said via pattern is transferred into a portion of said dielectric layer;
etching said first hard mask layer by using said second hard mask layer as a mask, wherein said via pattern is transferred into said dielectric layer; and
etching said dielectric layer by using said first hard mask layer as a mask to form a via hole and a trench line in said dielectric layer, wherein said trench line is over said via hole, and said via hole exposes a portion of said substrate.

2. The method according to claim 1, wherein said first hard mask layer is silicon carbide.

3. The method according to claim 2. Wherein said second hard mask layer is silicon oxynitride.

4. The method according to claim 1, wherein said dielectric layer is low-dielectric constant layer.

5. The method according to claim 1, wherein said substrate comprises conductive layer under said via hole.

6. The method according to claim 5, wherein said conductive layer comprises copper.

7. The method according to claim 6, further comprising a stop layer between said conductive layer and said dielectric layer.

8. The method according to claim 7, further comprising a step of etching said bottom layer to expose a portion of said substrate after said step of etching said dielectric layer by using said first hard mask layer as a mask to form a via hole and a trench line in said dielectric layer.

9. A method for forming dual damascene structure without using gap-filling material, said method comprising:
providing a semiconductor structure having a substrate, a first dielectric layer on said substrate, an etch stop layer on said first dielectric layer, a second dielectric layer on said etch stop layer, a first hard mask layer on said second dielectric layer, and a second hard mask layer on said first hard mask layer;
forming a via pattern photoresist layer on said second hard mask layer;
etching said second hard mask layer by using said via pattern photoresist layer as a mask to transfer said via pattern into said second hard mask layer;
removing said via pattern photoresist layer;
forming a trench pattern photoresist layer on said second hard mask layer, wherein said trench pattern is over said via pattern;
etching said first hard mask layer by using said second hard mask layer as a mask to transfer said via pattern into said first hard mask layer;
etching said second hard mask layer by using said trench pattern photoresist layer as a mask to transfer said trench pattern into said second hard mask layer, wherein said via pattern is transferred into said second dielectric layer;
etching said first hard mask layer by using said second hard mask layer as a mask to transfer said trench pattern in to said first hard mask layer, wherein said via pattern is transfer into said etch stop layer; and
etching said first and second dielectric layers to form a via hole in said first dielectric layer and a trench line in said second dielectric layer, wherein said via hole exposes a portion of said substrate.

10. The method according to claim 9, wherein said first hard mask layer is silicon carbide.

11. The method according to claim 10, wherein said second hard mask layer is silicon oxynitride.

12. The method according to claim 9, wherein said first and said second dielectric layers are low-dielectric constant layer.

13. The method according to claim 9, wherein said substrate comprises conductive layer under said via hole.
